(19) United States
(12) Patent Application Publication
(10) Pub. No.: US 2015/0015130 A1
(43) Pub. Date: Jan. 15, 2015

(54) CASE

(71) Applicant: 3Y POWER TECHNOLOGY (TAIWAN), INC., Guishan Township (TW)

(72) Inventors: Shao-Feng LU, Guishan Township (TW); Yi-Chen KUAN, Guishan Township (TW)

(73) Assignee: 3Y POWER TECHNOLOGY (TAIWAN), INC., Guishan Township (TW)

(21) Appl. No.: 14/327,315

(22) Filed: Jul. 9, 2014

(30) Foreign Application Priority Data
Jul. 9, 2013 (TW) 102212930

(51) Int. Cl. H05K 5/00; H05K 5/02

(52) U.S. Cl. CPC H05K 5/0004; H05K 5/0217
USPC 312/265.5

(57) ABSTRACT

A case including a first housing and a second housing. The first housing includes a first board, a first side board extending upward from the first board, and a limiting board unit connected to the first side board. The limiting board unit and the first side board define a positioning slot that has a guiding slot part having an open top end extending vertically and a hooking slot part connected to the guiding slot part and extending horizontally. The second housing includes a second board, a second side board extending downward from the second board, and a hooking fin protruding from a bottom end of the second side board, being inserted in an inserting direction into the guiding slot part, and being moved in a sliding direction perpendicular to the inserting direction and hooked in the hooking slot part. Therefore, the case, when assembled, has a number of screws reduced.

### BACKGROUND OF THE INVENTION

1. Field of the Invention

This invention relates to cases, and, more particularly, to a case that is used in a power supply and has a number of screws reduced when the case is assembled.

2. Description of Related Art

With regard to the assembling process of a case of a power supply, screws are used to fix a housing to another housing in a manner that the screws extend to a region inside the case and occupy some spaces in the case. As a result, the space in the case available for receiving electronic components is reduced. Beside, the portion of the screws that is in the case is likely in electrical contact with the electronic components such that the electronic components are malfunctioned.

Therefore, how to develop a novel case that can overcome the drawbacks in the prior art is becoming an urgent issue in the art.

### SUMMARY OF THE INVENTION

Therefore, the objective of the present invention is to provide a case that, when being assembled, has a number of screws reduced.

A case according to the present invention comprises: a first housing, comprising: a first board; a first side board extending upward from the first board; and a limiting board unit connected to the first side board, the limiting board and the first side board defining a positioning slot that has a guiding slot part having an opening top end extending vertically and a hooking slot part connected to a bottom end of the guiding slot part and extending horizontally; and a second housing, comprising: a second board; a second side board extending downward from the second board; and a hooking fin protruding from a bottom end of the second side board, the hooking fin being inserted in an inserting direction into the guiding slot part, and being moved in a sliding direction perpendicular to the inserting direction and hooked in the hooking slot part.

Preferably, the limiting board unit includes two limiting boards spaced apart from each other in the sliding direction, each of the limiting boards having a bending board part connected to the first side board, an extending board part extending upward from the bending board part, and a protruding board part protruding horizontally from the extending board part; the protruding board part of one of the limiting boards and the extending board part of the other one of the limiting boards define the guiding slot part, and the protruding board part and the extending board part of the one of the limiting boards and the first side board define the hooking slot part.

Preferably, the hooking fin includes a bending segment connected to the second side board and an extending segment extending downward from the bending segment; and when the hooking fin is hooked in the hooking slot part, the protruding board part of the one of the limiting boards is located above the extending segment and adjacent to the bending segment.

Preferably, the first side board has an inner surface, the second side board has an inner surface, and when the hooking fin is hooked in the hooking slot part, the extending segment of the hooking fin is adjacent to the inner surface of the first side board, and the extending board parts and the protruding board parts of the limiting boards are adjacent to the inner surface of the second side board.

Preferably, the first housing comprises two first side boards spaced apart from each other and two limiting board units connected to the two first side boards respectively, each of the limiting board units has a plurality of limiting boards, and the limiting boards of each of the limiting board units and the corresponding first side board define a plurality of positioning slots; the second housing comprises two second side boards spaced apart from each other and corresponding to the two first side boards respectively, and a plurality of hooking fins corresponding to the positioning slots.

Preferably, the first housing further comprises two first connection boards extending upward from the first board and connected to the first connection boards of the first side boards respectively, a second connection board spaced in parallel with the first board and connected to the first connection boards, and a first locking board connected to the second connection board; the second housing further comprises a second locking board connected to the second board, the second board is locked to the first locking board via a screw, and the second connection board is locked to the second locking board via another screw.

According to the present invention, the first housing and the second housing are engaged with each other via the limiting board unit and the hooking fin. Therefore, a number of screws used is reduced, and a receiving space available in the case is increased. Besides, electronic components installed in the case will not be in electrical contact with the case, and the case has an assembling process simplified.

### BRIEF DESCRIPTION OF DRAWINGS

The invention can be more fully understood by reading the following detailed description of the preferred embodiments, with reference made to the accompanying drawings, wherein:

FIG. 1 is an exploded view of a case of an embodiment according to the present invention;

FIG. 2 is a partial perspective view of a first housing of the embodiment according to the present invention;

FIG. 3 is a partial perspective view of a second housing of the embodiment according to the present invention;

FIG. 4 is a partial perspective view of the embodiment according to the present invention, illustrating a plurality of hooking fins of the first housing extending in an insertion direction into a plurality of corresponding guiding slot parts;

FIG. 5 is a partial perspective view of the embodiment according to the present invention, illustrating the hooking fins extending in a sliding direction perpendicular to the insertion direction and hooked in the hooking slot parts;

FIG. 6 is a cross-sectional view of the embodiment shown in FIG. 5; and

FIG. 7 is a perspective view of the embodiment according to the present invention, illustrating the first housing and the second housing being locked via two screws.

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

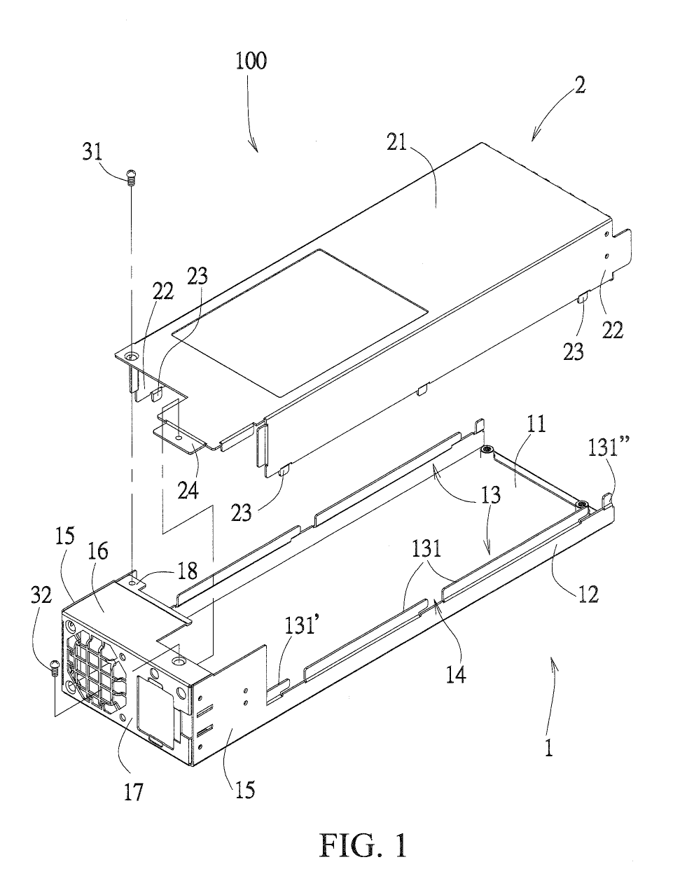

Refer to FIG. 1, which illustrates a case 100 of an embodiment according to the present invention. The case 100 comprises a first housing 1 and a second housing 2. In the present embodiment, the case 100 is used for receiving an electronic component (not shown) such as a power supplying module.

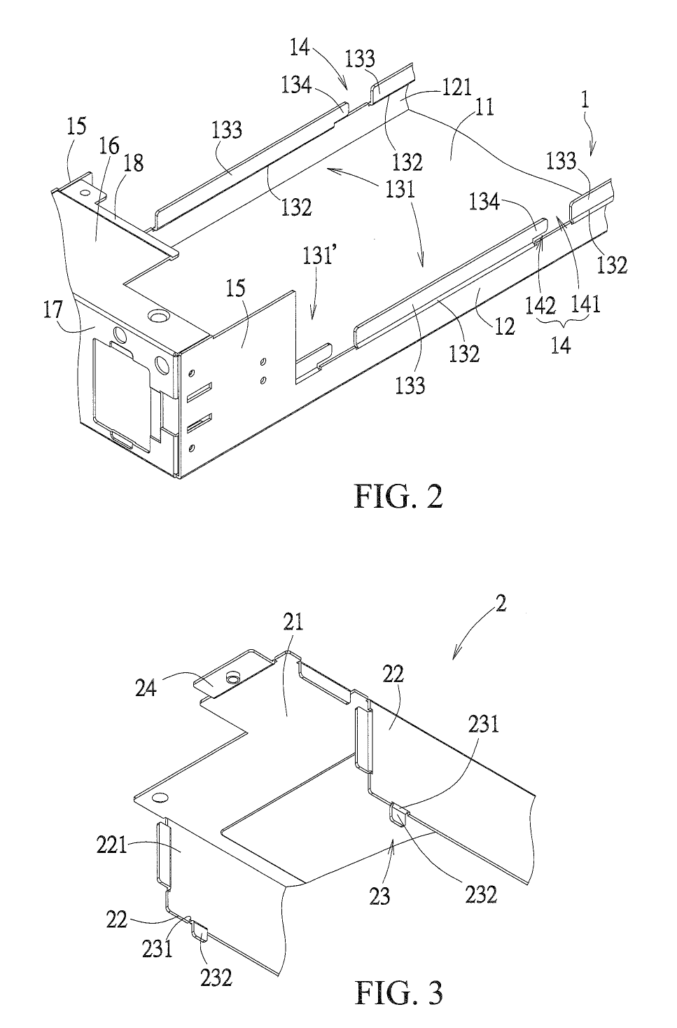

Refer to FIGS. 1 and 2. The first housing 1 comprises a first board 11, two first side boards 12, two limiting board units 13, two first connection boards 15, a second connection board 16, a third connection board 17, and a first locking board 18. The first board 11 is rectangular. The first side boards 12 extend upward from two opposing side edges of the first board 11. Each one of the first side boards 12 has an inner surface 121 facing to the other one of the first side boards 12.

The limiting board units 13 are connected to the top edges of the first side boards 12 respectively. Each of the limiting board units 13 and the corresponding first side board 12 define a plurality of positioning slots 14. Each of the positioning slots 14 has a guiding slot part 141 having an open top end extending vertically and a hooking slot part 142 connected to a bottom end of the guiding slot part 141 and extending horizontally. In the present embodiment, each of the limiting board units 13 has a plurality of limiting board 131, 131′ and 131″ in the length direction of the corresponding first side board 12. Each of the limiting boards 131 and 131′ has a bending board part 132 connected to a top edge of the first side board 12, an extending board part 133 extending upward from a top edge of the bending board part 132, and a protruding board part 134 protruding horizontally from the extending board part 133. The protruding board part 134 of each of the limiting boards 131 and 131′ and the extending board part 133 of the neighboring one of the limiting boards 131 and 131″ define a guiding slot part 141. The protruding board part 134 and the extending board part 133 of each of the limiting boards 131 and 131′ and the corresponding first side board 12 define a hooking slot part 142.

In the present embodiment, each of the limiting board units 13 has two limiting boards 131, a limiting board 131′, and a limiting board 131″. The limiting boards 131′ and 131″ are shorter than the limiting board 131. The limiting board 131″ has a bending board part 132 and an extending board part 133 only. In other words, the limiting board 131″ does not have a protruding board part 134.

The first connection boards 15 extend upward from two opposing side edges of the first board 11 and connected to the first side boards 12 respectively. The second connection board 16 is spaced in parallel with the first board 11 and connected to the top edges of the first connection boards 15. The third connection board 17 is connected to the first board 11, the first connection boards 15 and the second connection board 16. The first locking board 18 is connected to and protrudes from the second connection board 16.

Refer to FIGS. 1-3. The second housing 2 comprises a second board 21, two second side boards 22, a plurality of hooking fins 23 corresponding to the positioning slots 14 respectively, and a second locking board 24. The second board 21 is rectangular. The second side boards 22 extend downward from two opposing side edges of the second board 21. Each one of the second side boards 22 has an inner surface 221 facing to the other one of the second side boards 22. The hooking fins 23 protrude from the bottom ends of the second side boards 22. In the present embodiment, three of the hooking fins 23 protrude from one of the second side boards 22, and another three of the hooking fins 23 protrude from the other one of the second side boards 22. Each of the hooking fins 23 has a bending segment 231 connected to the corresponding second side board 22 and an extending segment 232 protruding downward from the bending segment 231. The second locking board 24 is connected to and protrudes from the second board 21.

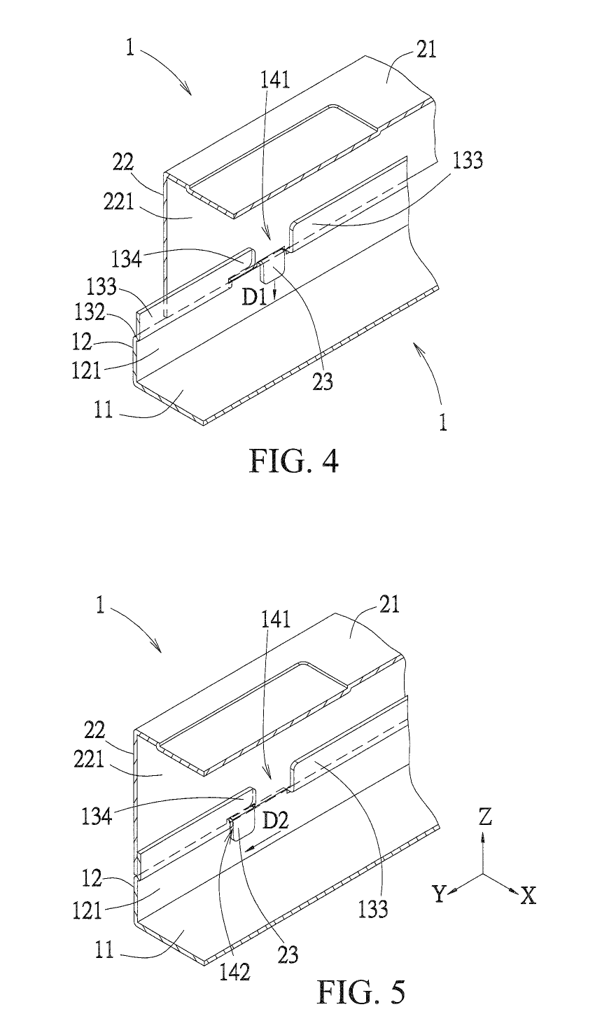

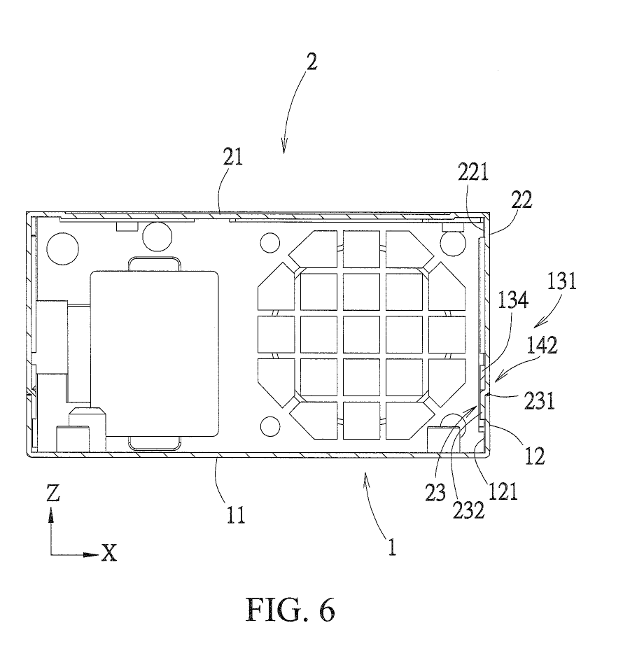

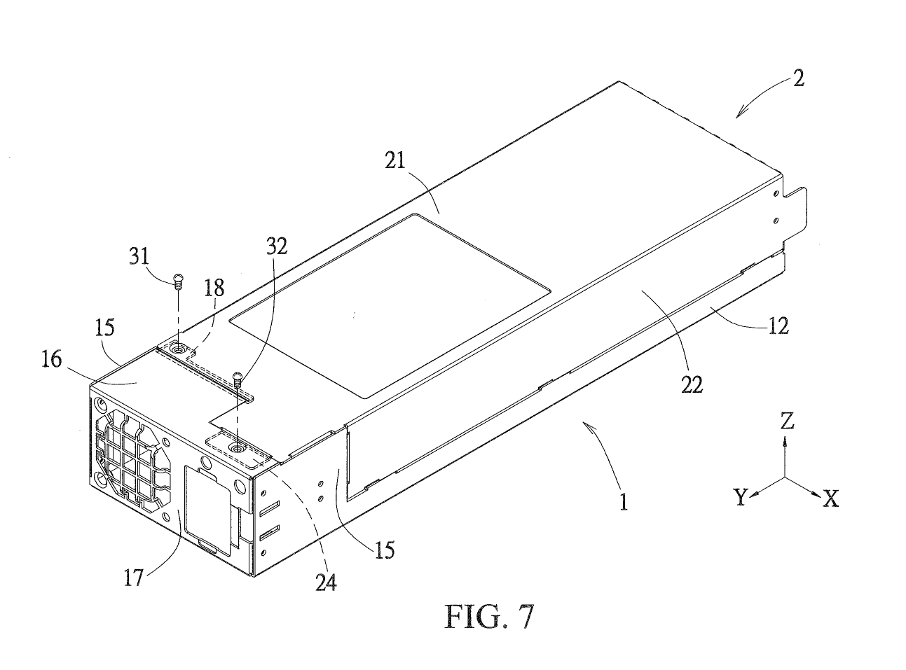

Refer to FIG. 4. When the case 100 is assembled, each of the hooking fins 23 are inserted in an inserting direction D1 into the corresponding guiding slot part 141. As shown in FIGS. 5 and 6, each of the hooking fins 23 are moved in a sliding direction D2 perpendicular to the inserting direction D1 and hooked in the corresponding hooking slot part 142. When each of the hooking fins 23 is hooked in the corresponding hooking slot part 142, the extending segment 232 of the hooking fin 23 is adjacent to the inner surface 121 of the first side board 12, and the extending board part 133 and the protruding board part 134 are adjacent to the inner surface 221 of the second side board 22. Therefore, the second housing 2 is limited along the x axis shown in FIGS. 5 and 6. When each of the hooking fins 23 is hooked in the corresponding hooking slot part 142, the protruding board part 134 of the hooking slot part 142 is disposed above the extending segment 232 of the hooking fin 23 and adjacent to the bending segment 231. Therefore, the second housing 2 is limited along the z direction shown in FIGS. 5 and 6.

As shown in FIG. 6, when each of the hooking fins 23 is hooked in the corresponding hooking slot part 142 (shown in FIG. 5), the second board 21 of the second housing 2 is stacked on the first locking board 18 of the first housing 1, and the second connection board 16 of the first housing 1 is stacked on the second locking board 24 of the second housing 2. In the last step of the assembling process, a screw 31 locks the second board 21 to the first locking board 18, and another screw 32 locks the second connection board 16 to the second locking board 24. Therefore, the second housing 2 is limited along the y axis shown in FIG. 6 for being connected to the first housing 1.

In the case 100 according to the present invention, the first housing 1 and the second housing 2 are engaged through the limiting board units 13 and the hooking fins 23. Therefore, a number of screws used is reduced, and a receiving space available in the case 100 is increased. Besides, electronic components installed in the case 100 will not be in electrical contact with the case 100, and the case 100 has an assembling process simplified.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A case, comprising:
a first housing, comprising:
a first board;
a first side board extending upward from the first board; and
a limiting board unit connected to the first side board, the limiting board and the first side board defining a positioning slot that has a guiding slot part having an opening top end extending vertically and a hooking slot part connected to a bottom end of the guiding slot part and extending horizontally; and
a second housing, comprising:
a second board;
a second side board extending downward from the second board; and
a hooking fin protruding from a bottom end of the second side board, the hooking fin being inserted in an inserting direction into the guiding slot part and being moved in a sliding direction perpendicular to the inserting direction and hooked in the hooking slot part.

2. The case of claim 1, wherein the limiting board unit includes two limiting boards spaced apart from each other in the sliding direction, each of the limiting boards having a bending board part connected to the first side board, an extending board part extending upward from the bending board part, and a protruding board part protruding horizontally from the extending board part.

3. The case of claim 2, wherein the protruding board part of one of the limiting boards and the extending board part of the other one of the limiting boards define the guiding slot part, and the protruding board part and the extending board part of the one of the limiting boards and the first side board define the hooking slot part.

4. The case of claim 3, wherein the hooking fin includes a bending segment connected to the second side board and an extending segment extending downward from the bending segment.

5. The case of claim 4, wherein when the hooking fin is hooked in the hooking slot part, the protruding board part of the one of the limiting boards is located above the extending segment and adjacent to the bending segment.

6. The case of claim 5, wherein the first side board has an inner surface, the second side board has an inner surface, and when the hooking fin is hooked in the hooking slot part, the extending segment of the hooking fin is adjacent to the inner surface of the first side board, and the extending board parts and the protruding board parts of the limiting boards are adjacent to the inner surface of the second side board.

7. The case of claim 6, wherein the first housing comprises two first side boards spaced apart from each other and two limiting board units connected to the two first side boards respectively, each of the limiting board units has a plurality of limiting boards, and the limiting boards of each of the limiting board units and the corresponding first side board define a plurality of positioning slots.

8. The case of claim 7, wherein the second housing comprises two second side boards spaced apart from each other and corresponding to the two first side boards respectively, and a plurality of hooking fins corresponding to the positioning slots.

9. The case of claim 8, wherein the first housing further comprises two first connection boards extending upward from the first board and connected to the first connection boards of the first side boards respectively, a second connection board spaced in parallel with the first board and connected to the first connection boards, and a first locking board connected to the second connection board.

10. The case of claim 9, wherein the second housing further comprises a second locking board connected to the second board, the second board is locked to the first locking board via a screw, and the second connection board is locked to the second locking board via another screw.
